(19) United States
(12) Patent Application Publication
(10) Pub. No.: US 2003/0022489 A1
(43) Pub. Date: Jan. 30, 2003

(54) Method of fabricating high melting point metal wiring layer, method of fabricating semiconductor device and semiconductor device

(75) Inventors: Shigenori Kido, Hyogo (JP); Takeshi Kishida, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/139,380

(22) Filed: May 7, 2002

(30) Foreign Application Priority Data
Jul. 24, 2001 (JP) 2001-222741 (P)

(51) Int. Cl. H01L 21/44; H01L 21/4763

(52) U.S. Cl. 438/659; 438/597; 438/660; 438/658

(57) ABSTRACT

In order to provide a method of fabricating a high melting point metal wiring layer improved to be capable of forming a thin line without employing a mask, a gate oxide film is formed on a semiconductor substrate. A silicon layer is formed on the gate oxide film. A high melting point metal layer is formed on the silicon layer. A mixed layer of the silicon layer and the high melting point metal layer is formed on a portion for defining a wiring layer. Remaining parts of the silicon layer and the high melting point metal layer other than those forming the mixed layer are removed by etching thereby forming a wiring layer. The wiring layer is heat-treated.

### BACKGROUND OF THE INVENTION

1. Field of the Invention

The present invention generally relates to a method of fabricating a high melting point metal wiring layer, and more specifically, it relates to a method of fabricating a high melting point metal wiring layer improved to be capable of patterning the layer without employing a photoresist mask. The present invention also relates to a method of fabricating a semiconductor device including steps of forming such a high melting point metal wiring layer. The present invention further relates to a semiconductor device obtained by such a method.

2. Description of the Prior Art

A conventional method of fabricating a field-effect transistor (hereinafter referred to as a MOSFET) including a step of forming a gate electrode relevant to the present invention is now described.

Referring to FIG. 6, a gate oxide film 2 and element isolation oxide films 3 are formed on the surface of a semiconductor substrate 1. A polysilicon layer 4 is formed on the gate oxide film 2.

Referring to FIGS. 6 and 7, the polysilicon layer 4 and the gate oxide film 2 are patterned through a mask of a photoresist pattern, for forming a gate electrode 5.

Referring to FIG. 8, the gate electrode 5 is employed as a mask for implanting impurity ions into the surface of the semiconductor substrate 1, thereby forming source/drain regions 6 and 7.

Referring to FIG. 9, an interlayer isolation film 8 is formed on the semiconductor substrate 1 to cover the gate electrode 5. Contact holes 8a partially exposing the surfaces of the source/drain regions 6 and 7 are formed in the interlayer isolation film 8. Aluminum wires 9 are formed to be connected to the source/drain regions 6 and 7 through the contact holes 8a.

In order to reduce the resistance of the gate electrode 5, high melting point metal silicide is recently employed.

In the conventional method of fabricating a MOSFET, as hereinabove described, the gate electrode 5 is patterned through a photoresist mask, as shown in FIG. 7.

However, the step employing the photoresist mask is disadvantageous for patterning a small area in consideration of the cost required for preparing the mask etc.

### SUMMARY OF THE INVENTION

The present invention has been proposed for solving the aforementioned problem, and an object thereof is to provide a method of fabricating a high melting point metal wiring layer improved to be capable of advantageously patterning a small area.

Another object of the present invention is to provide a method of fabricating a semiconductor device including steps of forming the aforementioned high melting point metal wiring layer.

Still another object of the present invention is to provide a semiconductor device obtained by such a fabrication method.

In the method of fabricating a high melting point metal wiring layer according to the present invention, a silicon layer is first formed on a semiconductor substrate. A high melting point metal layer is formed on the aforementioned silicon layer. A mixed layer of the aforementioned silicon layer and the aforementioned high melting point metal layer is formed on a portion for defining a wiring layer. Remaining parts of the aforementioned silicon layer and the aforementioned high melting point metal layer other than those forming the aforementioned mixed layer are removed by etching thereby forming a wiring layer. The aforementioned wiring layer is heat-treated.

According to a preferred mode of the present invention, the step of forming the aforementioned mixed layer includes a step of applying ions to the aforementioned portion for defining a wiring layer at an energy level so selected as to implant the ions into the boundary between the aforementioned silicon layer and the aforementioned high melting point metal layer.

The aforementioned ions are preferably applied without employing a mask.

The thicknesses of the aforementioned silicon layer and the aforementioned high melting point metal layer are preferably so selected that the ratio of the numbers of atoms forming the silicon layer and the high melting point metal layer is 2:1 respectively.

The aforementioned silicon layer includes a polysilicon layer or an amorphous silicon layer.

The aforementioned ions include ions of inert gas. The ions of the inert gas include ions of Ar.

The aforementioned ions are preferably applied with a focused ion beam.

The aforementioned high melting point metal layer contains Co, Ti or W.

The aforementioned wiring layer includes a gate wire.

In the method of fabricating a semiconductor device according to another aspect of the present invention, a silicon layer is formed on a semiconductor substrate. A high melting point metal layer is formed on the aforementioned silicon layer. A mixed layer of the aforementioned silicon layer and the aforementioned high melting point metal layer is formed on a portion for defining a wiring layer. Remaining parts of the aforementioned silicon layer and the aforementioned high melting point metal layer other than those forming the aforementioned mixed layer are removed by etching thereby forming a wiring layer. The aforementioned wiring layer is heat-treated.

The semiconductor device according to still another aspect of the present invention comprises a semiconductor substrate. A wiring layer formed by a high melting point metal silicide layer is provided on the aforementioned semiconductor substrate. The aforementioned high melting point metal silicide layer contains an inert gas component.

The aforementioned inert gas component includes Ar.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 4 are sectional views of a semiconductor device showing first to fourth steps in a method of fabricating a high melting point metal wiring layer according to a first embodiment of the present invention;

FIG. 5 is a sectional view of a semiconductor device showing a principal step in a method of fabricating a high melting point metal wiring layer according to a second embodiment of the present invention; and

FIGS. 6 to 9 are sectional views of a semiconductor device showing first to fourth steps in a conventional method of fabricating a MOSFET.

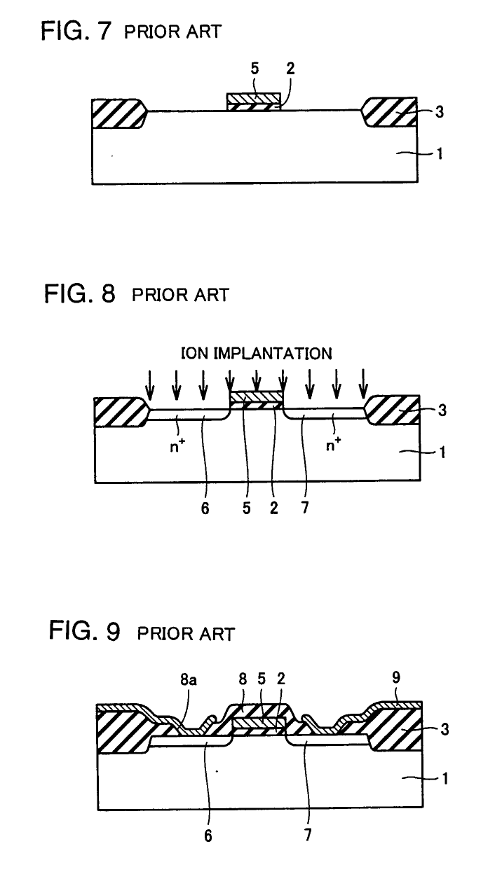

### DESCRIPTION OF THE PREFERRED EMBODIMENTS

Embodiments of the present invention are now described with reference to the drawings.

### FIRST EMBODIMENT

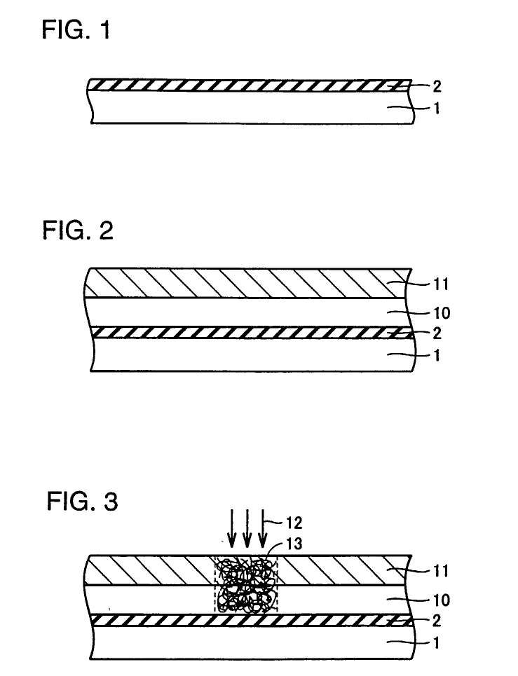

FIGS. 1 to 4 are sectional views of a semiconductor device showing steps in a method of fabricating a high melting point metal wiring layer according to a first embodiment of the present invention.

Referring to FIG. 1, a gate oxide film 2 is formed on a silicon substrate 1.

Referring to FIG. 2, a polysilicon layer 10 is formed on the gate oxide film 2. A high melting point metal layer 11 of Co, Ti or W is provided on the polysilicon layer 10. The polysilicon layer 10 and the high melting point metal layer 11 are deposited in such thicknesses that the ratio of the numbers of atoms forming the layers 10 and 11 is 2:1. The polysilicon layer 10 may be replaced with an amorphous silicon layer.

Referring to FIG. 3, ions 12 of Ar, which is inert gas, are applied to a portion for defining a wiring layer at an energy level so selected as to implant the ions 12 into the boundary between the polysilicon layer 10 and the high melting point metal layer 11. The dose of the ions 12 is 10¹⁴ to 10¹⁵ atoms/cm².

Thus, a mixed layer (consisting of Co₂Si, CoSi and CoSi₂) 13 of polysilicon and the high melting point metal is formed only on the portion for defining a wiring layer irradiated with the ions 12. While the ions 12 may be applied through a photomask, the target portion can be selectively irradiated with the ions 12 without through a mask when a focused ion beam is employed.

Referring to FIGS. 3 and 4, wet etching is successively performed on non-irradiated parts of the high melting point metal layer 11 and the polysilicon layer 10, thereby forming an electrode. The mixed layer 13, the polysilicon layer 10 and the high melting point metal layer 11 are different in etching rate from each other. Therefore, the non-irradiated parts of the high melting point metal layer 11 and the polysilicon layer 10 can be selectively removed by etching.

The mixed layer 13 is fully converted to CoSi₂ due to subsequent heat treatment. This is because the thicknesses of the polysilicon layer 10 and the high melting point metal layer 11 are so selected that the ratio of the numbers of the atoms forming these layers 10 and 11 is 2:1. The resulting CoSi₂ has a low resistance value of 10 to 20 μΩ. Therefore, the mixed layer 13 defines a gate electrode having low resistance.

The gate electrode consisting of metal silicide formed in the aforementioned manner contains Ar atoms.

Thereafter steps similar to those of the prior art shown in FIGS. 8 and 9 are carried out thereby obtaining a MOSFET.

Thus, a thin line can be formed without through a mask when a focused ion beam is employed, for reducing the time and the cost for preparing a mask in a small area.

In the aforementioned embodiment, the ions 12 are prepared from inert gas. If active gas is employed, this gas may react with the polysilicon layer 10 and the high melting point metal layer 12 to exert bad influence on the conductivity of the gate electrode.

### SECOND EMBODIMENT

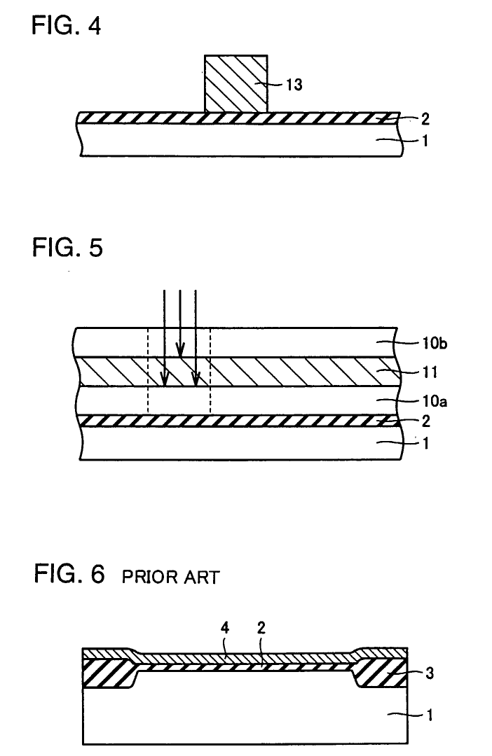

While the single high melting point metal layer 11 is formed on the single polysilicon layer 10 in the aforementioned first embodiment, the present invention is not restricted to this. According to a second embodiment of the present invention, a polysilicon layer 10a is formed on a silicon substrate 1 followed by formation of a high melting point metal layer 11 and another polysilicon layer 10b thereon, as shown in FIG. 5. The thicknesses of the polysilicon layers 10a and 10b and the high melting point metal layer 11 are so selected that the ratio of the numbers of silicon atoms and high melting point metal atoms is 2:1 along the vertical direction respectively. Then, ions of inert gas are implanted into the boundaries between the polysilicon layers 10a and 10b and the high melting point metal layer 11, for forming mixed layers. An effect similar to that of the first embodiment is attained also in this case.

While the high melting point metal is prepared from Co in the first embodiment, a silicide layer of WSi₂ is obtained when the high melting point metal is prepared from W, and a silicide layer of TiSi₂ is obtained when the high melting point metal is prepared from Ti.

According to the present invention, as hereinabove described, a thin line can be formed without through a mask by employing a focused ion beam, for effectively reducing the time and the cost for preparing a mask in a small area.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of fabricating a high melting point metal wiring layer comprising steps of:
forming a silicon layer on a semiconductor substrate;
forming a high melting point metal layer on said silicon layer;
forming a mixed layer of said silicon layer and said high melting point metal layer on a portion for defining a wiring layer;
removing remaining parts of said silicon layer and said high melting point metal layer other than parts forming said mixed layer by etching thereby forming a wiring layer; and
heat-treating said wiring layer.

2. The method of fabricating a high melting point metal wiring layer according to claim 1, wherein said step of forming said mixed layer includes a step of applying ions to said portion for defining a wiring layer at an energy level so selected as to implant said ions into the boundary between said silicon layer and said high melting point metal layer.

3. The method of fabricating a high melting point metal wiring layer according to claim 2, applying said ions without employing a mask.

4. The method of fabricating a high melting point metal wiring layer according to claim 1, wherein the thicknesses of said silicon layer and said high melting point metal layer are so selected that the ratio of the numbers of atoms forming said silicon layer and said high melting point metal layer is 2:1 respectively.

5. The method of fabricating a high melting point metal wiring layer according to claim 1, wherein said silicon layer includes a polysilicon layer or an amorphous silicon layer.

6. The method of fabricating a high melting point metal wiring layer according to claim 2, wherein said ions include ions of inert gas.

7. The method of fabricating a high melting point metal wiring layer according to claim 3, applying said ions with a focused ion beam.

8. The method of fabricating a high melting point metal wiring layer according to claim 6, wherein said ions of said inert gas include ions of Ar.

9. The method of fabricating a high melting point metal wiring layer according to claim 1, wherein said high melting point metal layer contains Co, Ti or W.

10. The method of fabricating a high melting point metal wiring layer according to claim 1, wherein said wiring layer includes a gate wire.

11. A method of fabricating a semiconductor device comprising steps of:
forming a silicon layer on a semiconductor substrate;
forming a high melting point metal layer on said silicon layer;
forming a mixed layer of said silicon layer and said high melting point metal layer on a portion for defining a wiring layer;
removing remaining parts of said silicon layer and said high melting point metal layer other than parts forming said mixed layer by etching thereby forming a wiring layer; and
heat-treating said wiring layer.

12. A semiconductor device comprising:
a semiconductor substrate; and
a wiring layer, formed by a high melting point metal silicide layer, provided on said semiconductor substrate, wherein
said high melting point metal silicide layer contains an inert gas component.

13. The semiconductor device according to claim 12, wherein said inert gas component includes Ar.
